(19) United States
(12) Patent Application Publication
(10) Pub. No.: US 2006/0200721 A1
(43) Pub. Date: Sep. 7, 2006

(54) Tester simulation system and tester simulation method using same

(75) Inventor: Fumihiko Kobayashi, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: YOKOGAWA ELECTRIC CORPORATION

(21) Appl. No.: 11/331,016

(22) Filed: Jan. 13, 2006

(30) Foreign Application Priority Data
Mar. 7, 2005 (JP) 2005-062085

(51) Int. Cl. G01R 31/28; G06F 11/00

(52) U.S. Cl. 714/741

(57) ABSTRACT

It is an object of the invention to implement a tester simulation system capable of finding margins of respective expected value determining timings in a short time, and a tester simulation method using the same. The invention is an improvement of a tester simulation system for executing a test of a device under test by use of a tester by running a simulation using a DUT model for simulating an operation of the device under test, and a tester model for simulating an operation of the tester. The tester simulation system is characterized in comprising a margin analyzing means for analyzing margins of respective expected value determining timings on the basis of output data of the DUT model.

### FIELD OF THE INVENTION

The invention relates to a tester simulation system for simulating a test of a device under test by use of a tester, and a tester simulation method using the same, and more particularly, to a tester simulation system capable of executing a simulation in which margins of respective expected value determining timings can be obtained in a short time, and a tester simulation method using the same.

### BACKGROUND OF THE INVENTION

A tester (an IC tester) is to provide a device under test (hereinafter referred to as a DUT) with an input pattern on the basis of a test program as shown in FIG. 14(A), and to compare an output from the DUT as shown in FIG. 14 (B) with an expected value pattern at expected value determining timings (also called strobes) as shown in FIG. 14 (C), thereby determining whether or not the DUT is acceptable. A simulation has lately been carried out using a DUT model and a tester model, before actually testing the DUT by use of a tester, thereby checking an operation of the test program. Such a system has since been disclosed in, for example, the following Patent Document 1, and so forth.

[Patent Document 1] JP 2003-256493 A

Taking a real tester in consideration, it is to be pointed out that a tester and a DUT each have a subtle fluctuation in electrical characteristics for every unity and for every test conducted. Accordingly, if the expected value determining timing is in the vicinity of a variation point of an output signal value, there is a possibility that the signal value at the expected value determining timing undergoes variation by the DUT, or by the tester due to the effect of such fluctuation in the electrical characteristics. As a result, there have occurred the cases where the DUT is determined as defective even though it is normal.

In order to control the effect of the fluctuation, the expected value determining timing is therefore preferably set in a region where the signal value is sufficiently stable even if there exists the subtle fluctuation in the electrical characteristics, or to put it the other way around, in the vicinity of the center of a region showing same result even if the expected value determining timing undergoes a slight change.

For this reason, it is important to know tolerance (time) for enabling the same determination to be made to whatever extent the expected value determining timing as set is deviated before or after. Such tolerance is referred to as a margin normal test, an input pattern and expected value determination are set based on a test rate. Accordingly, determining timing occurs for every test rate, and with the elapse of a predetermined time from the head of the test rate, the determining timing is caused to occur. Further, identical expected value determining timings are set for a plurality of the test rates against a plurality of output pins of the DUT, respectively. Accordingly, if operation conditions of a tester are changed, the expected value determining timing also undergoes a change for all the test rates. Therefore, the margin is to be considered not only for one of the test rates, but also for all the test rates where the identical expected value determining timing is set, referring to a region where the expected value determination can be stably implemented for all those test rates. A system developed to find the margin described as above is shown in FIG. 15, and is described hereinafter.

As shown in FIG. 15, a memory 1 stores a test program including test patterns comprising input patterns, expected value pattern, and so forth. A simulation means 2 simulates a circuit operation of a tester on the basis of the test program of the memory 1. The simulation means 2 has a tester model 21, and a DUT model 22. The tester model 21 simulates the circuit operation of the tester on the basis of the test program of the memory 1. The DUT model 22 exchanges a signal with the tester model 21 to thereby simulate a circuit operation of the DUT such as, for example, an IC, an LSI, and so forth. A margin analyzing means 3 has a setting means 31, and a margin computing means 32. The setting means 31 executes setting of the test program of the memory 1. The margin computing means 32 computes a margin on the basis of setting data of the setting means 31, and a pass or a fail, sent out from the tester model 21 of the simulation means 2.

Now, an operation of such a system as described above is described with reference to FIGS. 16 and 17. FIGS. 16 and 17 are a flow chart, and a timing chart, respectively, showing the operation of the system shown in FIG. 15. FIG. 17(A) shows the input pattern of the DUT model 22, FIG. 17(B) shows the output of the DUT model 22, and FIG. 17(C) shows the expected value determining timing while t0 indicates expected value determining timing set in the test program at first.

The setting means 31 of the margin analyzing means 3 sets an initial value S of the expected value determining timing, as the setting data, against the test program of the memory 1 (S1). The simulation means 2 reads the test program of the memory 1, and operates the tester model 21 according to the test program. The tester model 21 outputs the input pattern to the DUT model 22 based on the test program as shown in FIG. 17 (A). The DUT model 22 executes outputting to the tester model 21 according to the input pattern, as shown in FIG. 17 (B). Then, the tester model 21 compares the output of the DUT model 22 with the expected value pattern of the test program at the expected value determining timing as shown in FIG. 17 (C), thereby determining a pass or a fail (S2).

The margin computing means 32 of the margin analyzing means 3 acquires pass/fail data of the tester model 21 of the simulation means 2 (S3). Subsequently, the setting means 31 determines whether or not the expected value determining timing is equivalent to a completion value E or greater (S4), and if the same is smaller than the completion value E, the setting means 31 adds Δt to the setting data, whereupon the setting data with Δt added thereto is set in the test program of the memory 1 (S5). The simulation means 2 again executes the simulation as described above (S2). If the expected value determining timing is equivalent to the completion value E or greater, the margin computing means 32 computes a margin. That is, the margin computing means 32 finds timing as passed, falling between the minimum value and the maximum value, as the margin (S6).

### SUMMARY OF THE INVENTION

In the case of testing an LSI, a simulation by the simulation means 2 takes many hours. Accordingly, a problem has been encountered in that it takes more hours several times as many to find margins by repeatedly executing the simulations therefore an object of the invention to implement a tester simulation system capable of finding margins of respective expected value determining timings in a short time, and a tester simulation method using the same.

To that end, the invention provides in its first aspect a tester simulation system for executing a test of a device under test by use of a tester by running a simulation using a DUT model for simulating an operation of the device under test, and a tester model for simulating an operation of the tester, wherein the tester simulation system comprises a margin analyzing means for analyzing margins of respective expected value determining timings on the basis of output data of the DUT model.

With the tester simulation system having these features, the margin analyzing means preferably finds the margins at least in the cases of a fail on the basis of pass/fail determination data representing results of comparison of the output data of the DUT model with an expected value pattern.

With those features, the margin analyzing means may comprise a stable region extraction means for extracting stable regions of the output data of the DUT model in respective check ranges, and a margin determining means for determining the respective margins of the expected value determining timings from results of the stable region extraction means with those features, the margin analyzing means may comprise an expected value comparison means for comparing the output data of the DUT model with the respective expected value patterns according to checkpoints as expected value determining timings, and a margin determining means for determining the respective margins of the expected value determining timings from results of the expected value comparison means.

Still further, the tester simulation system with those features preferably comprises an acquisition means for acquiring at least the output data of the DUT model for use in the margin analyzing means.

The invention provides in its second aspect a tester simulation method for executing a test of a device under test by use of a tester by running a simulation using a DUT model for simulating an operation of the device under test, and a tester model for simulating an operation of the tester, said method comprising the step of analyzing margins of respective expected value determining timings on the basis of output data of the DUT model.

With those features, said method may comprise the step of finding margins at least in the cases of a fail on the basis of pass/fail determination data representing results of comparison of the output data of the DUT model with respective expected value patterns.

With those features, said method may further comprise the steps of extracting stable regions of the output data of the DUT model in respective check ranges, and determining the respective margins of the expected value determining timings from the respective stable regions.

With those features, said method may further comprise the steps of comparing the output data of the DUT model with the respective expected value patterns according to checkpoints as expected value determining timings, and determining the respective margins of the expected value determining timings from results of comparison.

The invention has the following advantageous effects.

According to the first aspect of the invention, since the margin analyzing means analyzes the respective margins of the expected value determining timings on the basis of the output data of the DUT model, the respective margins can be obtained in a short time.

Further, since the margin analyzing means finds the respective margins of the expected value determining timings, at the time of fails, from the output data and the pass/fail determination data, it is possible to find whether or not the expected value comparison results can be passed in all the test rates by changing the expected value determining timing if the margins are small.

Still further, since the stable region is found in the respective check ranges, it is possible to find correct margins.

According to the second aspect of the invention, since the respective margins of the expected value determining timings are found on the basis of the output data of the DUT model, the respective margins can be obtained in a short time.

Further, since the respective margins of the expected value determining timings, at the time of fails, are found from the output data and the pass/fail determination data, it is possible to find whether or not the expected value comparison results can be passed in all the test rates by changing the expected value determining timing if the margins are small.

Still further, since the stable region is found in the respective check ranges, it is possible to find correct margins.

### BRIEF DESCRIPTION OF THE DRAWINGS

FIG. 1 is a block diagram of a first embodiment of a tester simulation system according to the invention;

FIGS. 2A and 2B are schematic views illustrating an operation of the system shown in FIG. 1;

FIGS. 3A and 3B are schematic views illustrating another operation of the system shown in FIG. 1;

FIG. 4 is a block diagram of a second embodiment of a tester simulation system according to the invention;

FIG. 5 is a block diagram of a third embodiment of a tester simulation system according to the invention;

FIGS. 6A and 6B are schematic views illustrating an operation of the system shown in FIG. 5;

FIG. 7 is a block diagram of a fourth embodiment of a tester simulation system according to the invention;

FIGS. 8A and 8B are schematic views illustrating an operation of the system shown in FIG. 7;

FIG. 9 is a block diagram of a fifth embodiment of a tester simulation system according to the invention;

FIGS. 10A, 10B and 10C are schematic views illustrating an operation of the system shown in FIG. 9;

FIG. 11 is a block diagram of a sixth embodiment of a tester simulation system according to the invention;

FIGS. 12A and 12B are schematic views illustrating an operation of the system shown in FIG. 11;

FIG. 13 is a block diagram of a seventh embodiment of a tester simulation system according to the invention;

FIGS. 14A, 14B and 14C are timing charts for illustrating an operation of a tester;

FIG. 15 is a block diagram showing a configuration of a conventional tester simulation system;

FIG. 16 is a flow chart showing an operation of the system shown in FIG. 15; and

FIGS. 17A, 17B and 17C are schematic views illustrating an operation of the system shown in FIG. 15.

### PREFERRED EMBODIMENTS OF THE INVENTION

Embodiments of the invention are described hereinafter with reference to the accompanying drawings.

### First Embodiment

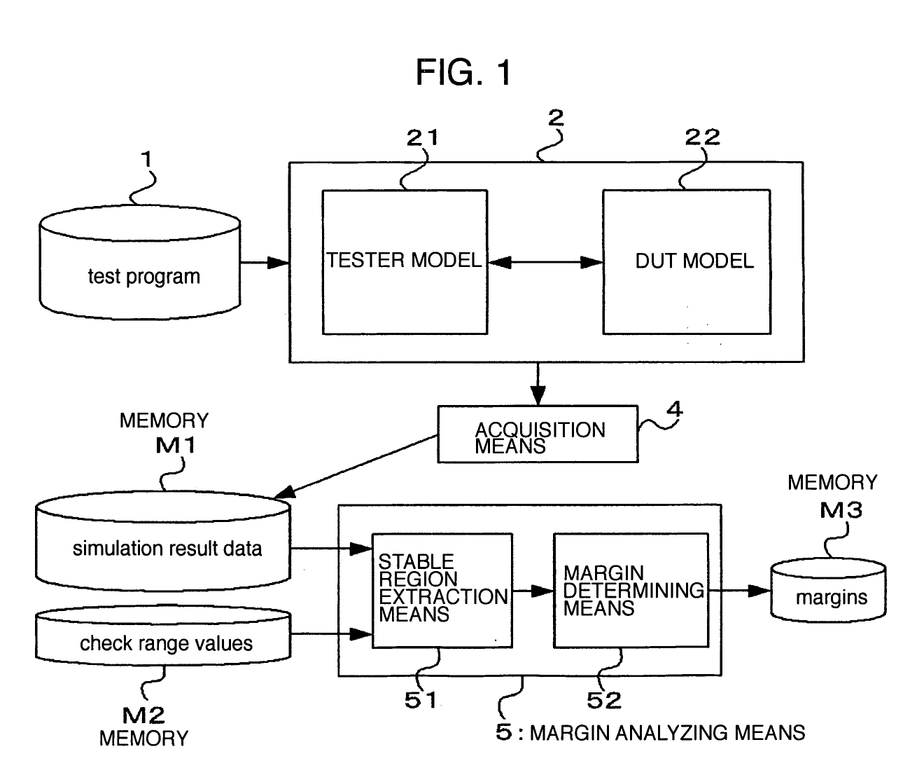

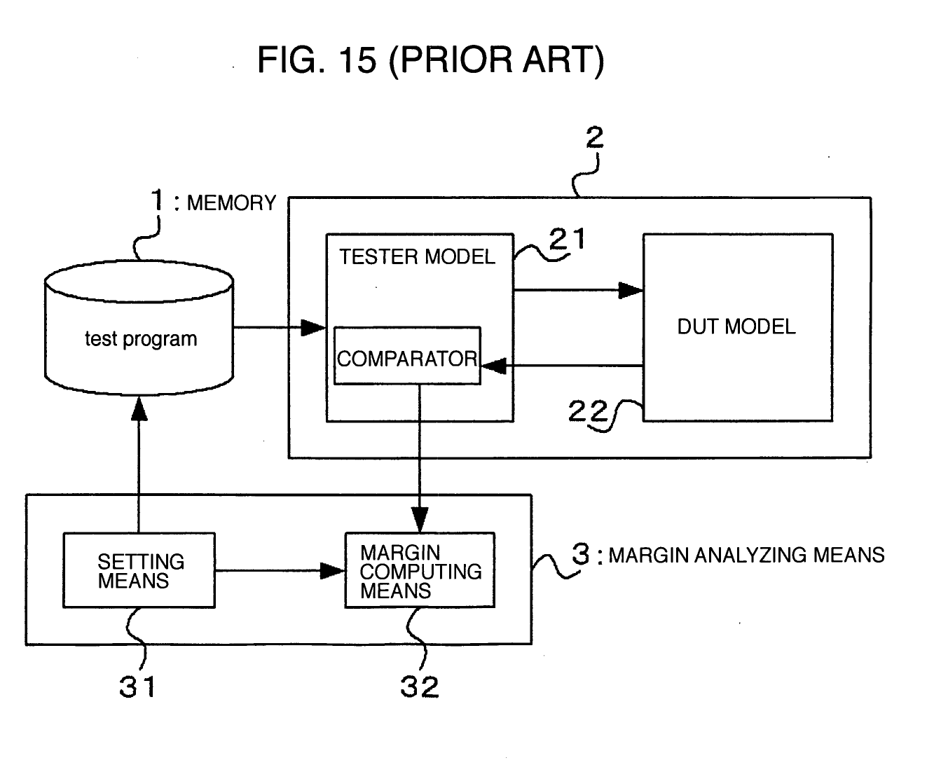

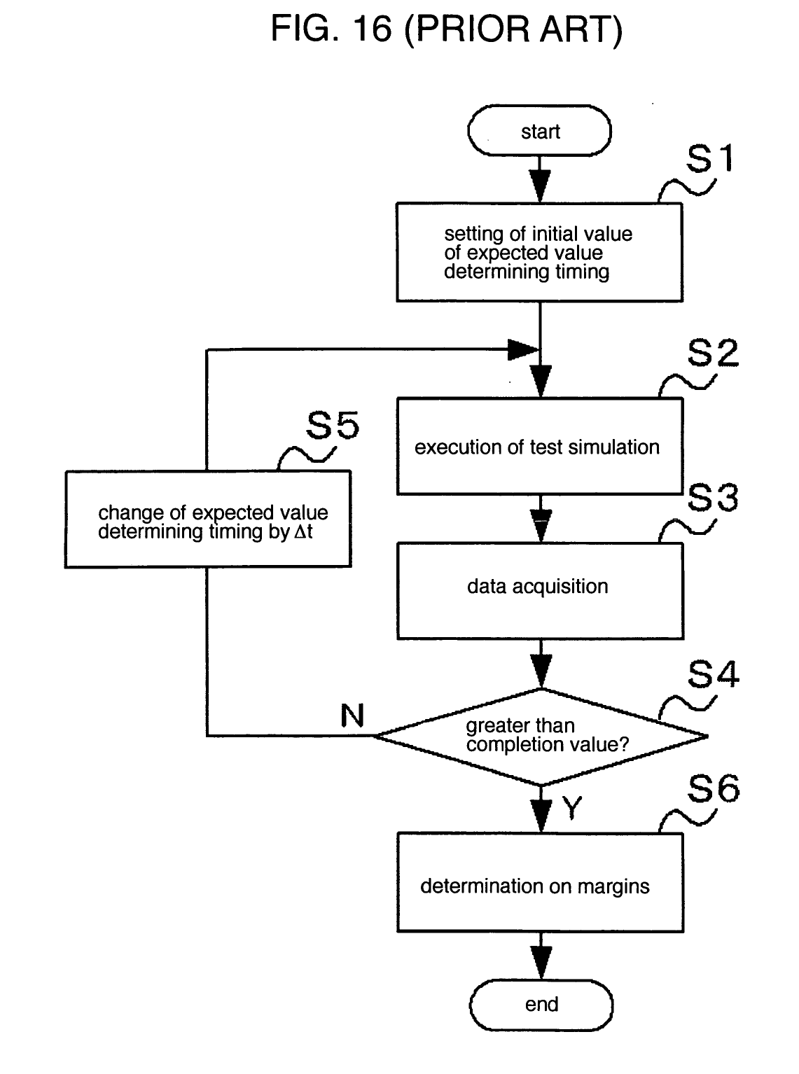

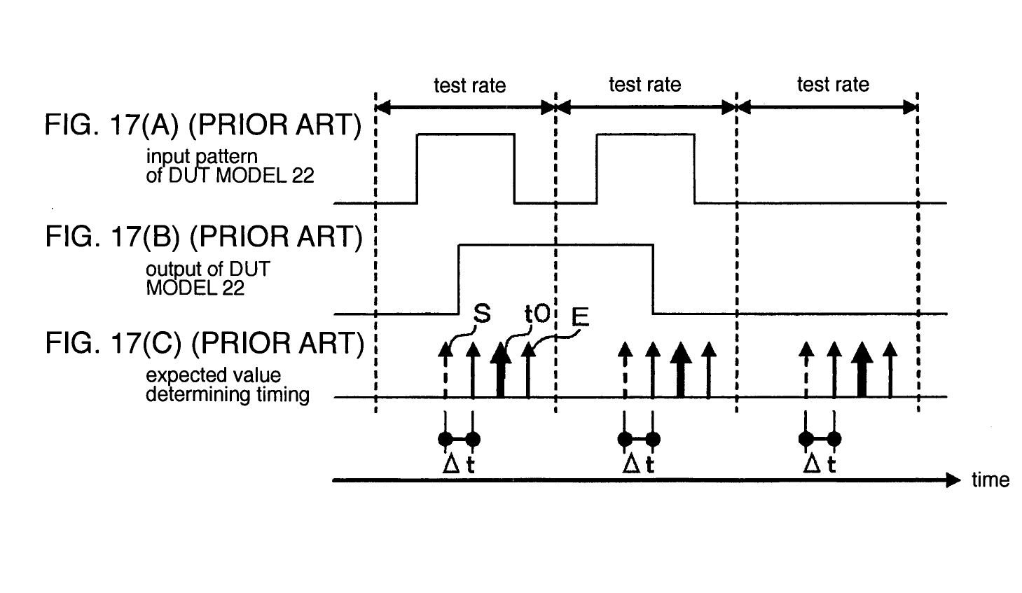

FIG. 1 is a block diagram of a first embodiment of a tester simulation system according to the invention. In the figure, parts identical to those in FIG. 15 are denoted by like reference numerals, and description thereof is omitted. With reference to other embodiments described hereinafter, parts identical to those in FIG. 1 are similarly denoted by like reference numerals, omitting description thereof.

As shown in FIG. 1, an acquisition means 4 acquires simulation result data of a tester model 21 as well as a DUT model 22 of a simulation means 2. A memory M1 stores the data received from the acquisition means 4. A memory M2 stores check range values for checking margins of respective expected value determining timings. A memory M3 stores the respective margins of the expected value determining timings. A margin analyzing means 5 analyzes the respective margins of the expected value determining timings on the basis of output data of the simulation result data as well as expected value determining timing data of the memory M1, and the check range values of the memory M2 to thereby store the respective margins of the expected value determining timings in the memory M3. The margin analyzing means 5 comprises a stable region extraction means 51, and a margin determining means 52. The stable region extraction means 51 extracts stable regions of output data of the memory M2 at the respective check range values for every expected value determining timing according to the expected value determining timing data. The margin determining means 52 determines the respective margins of the expected value determining timings from results of the stable region extraction means 51.

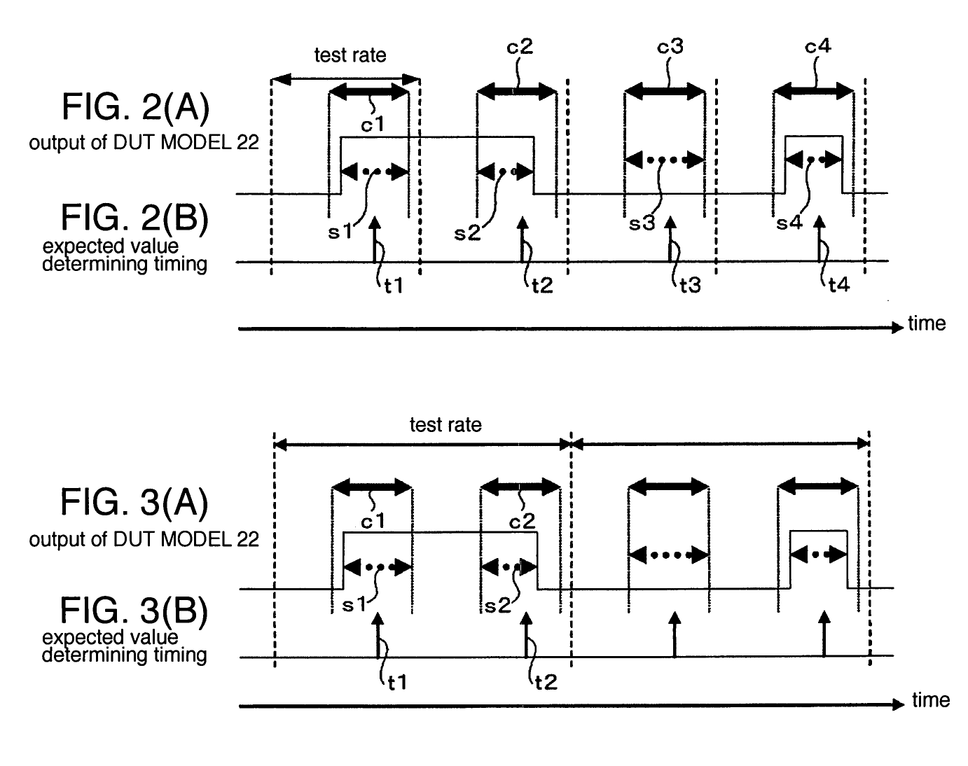

Now, an operation of such a system as described above is described with reference to FIG. 2. FIG. 2 is a schematic view illustrating the operation of the system shown in FIG. 1. FIG. 2(A) indicates an output signal of the DUT model 22, and FIG. 2(B) the expected value determining timing.

The simulation means 2 reads a test program of a memory 1, and operates the tester model 21 according to the test program. The tester model 21 outputs an input pattern to the DUT model 22 on the basis of the test program. The DUT model 22 executes outputting to the tester model 21 according to the input pattern. Then, the tester model 21 compares an output of the DUT model 22 with an expected value pattern of the test program. At this point in time, the acquisition means 4 acquires at least the expected value determining timing data of the tester model 21 of the simulation means 2, and output data of the DUT model 22 to be thereby stored in the memory M1. Herein, the expected value determining timing data, and the output data are normally expressed in terms of signal value and signal change-time.

The stable region extraction means 51 of the margin analyzing means 5 finds a check range c1 from expected value determining timing t1, and the check range values of the memory M2, as shown in FIG. 2, according to the expected value determining timing data from the memory M1. More specifically, the minimum time and the maximum time of the check range c1 are found. Subsequently, the stable region extraction means 51 extracts a stable region s1 where an output data signal of the memory M2 undergoes no change within the check range c1. More specifically, the stable region extraction means 51 determines whether or not the signal has undergone a change within the check range by comparing a time of the expected value determining timing with an output data signal change-time. The stable region extraction means 51 similarly finds a check range c2 from expected value determining timing t2, and the check range values. Then, the stable region extraction means 51 extracts a stable region s2 where the output data signal undergoes no change within the check range c2. Such an operation as described in the foregoing is repeated to thereby extract stable regions s3, s4 within the check ranges c3, c4, at expected value determining timings subsequently respective margin determining means 52 of the margin analyzing means 5 finds portions of the respective extract stable regions, in which the signal undergoes no change, overlapping each other, even if all the expected value determining timings t1 to t4 are shifted before or after relative to respective test rates (relative to a starting point of a test rate for every test rate) from the stable regions s1 to s4, respectively, to thereby find the respective margins of the expected value determining timings, storing the same in the memory M3.

Thus, since the margin analyzing means 5 finds the respective margins of the expected value determining timings from the output data of the DUT model 22, the respective margins can be obtained in a short time. Further, since the margin is found in the respective check ranges, a correct margin can be found. That is, in the case of finding the margin by shifting the expected value determining timing by Δt in the simulation means 2, it is impossible to find the margin in case a fail occurs within Δt, however, with the present embodiment, since the margins found are for all the check ranges, the correct margin can be found.

Further, there can be the case where two expected value determining timings t1, t2 exist within one test rate as shown in FIG. 3, a configuration may be adopted wherein margins are found by similarly finding check ranges c1, c2 to thereby find stable regions s1, s2, respectively.

Still further, the acquisition means 4 may be of a configuration for acquiring all the simulation result data of the simulation means 2, or for acquiring only a necessary portion of the data. As to the expected value determining timings, since identical expected value determining timings are used by a plurality of comparators, the acquisition means 4 has no need for acquiring the expected value determining timings for all the comparators, and may acquire the expected value determining timings for one comparator.

Yet further, there is shown a configuration wherein the margin analyzing means 5 finds the margins on the basis of the check range values, respectively, however, the check range values are not necessarily needed. A configuration may be adopted wherein the margin analyzing means 5 finds the stable regions by finding respective variation points of the output data signals of the DUT model 22, closest to the respective expected value determining timings. Furthermore, the test rates are used as the check ranges, respectively.

### Second Embodiment

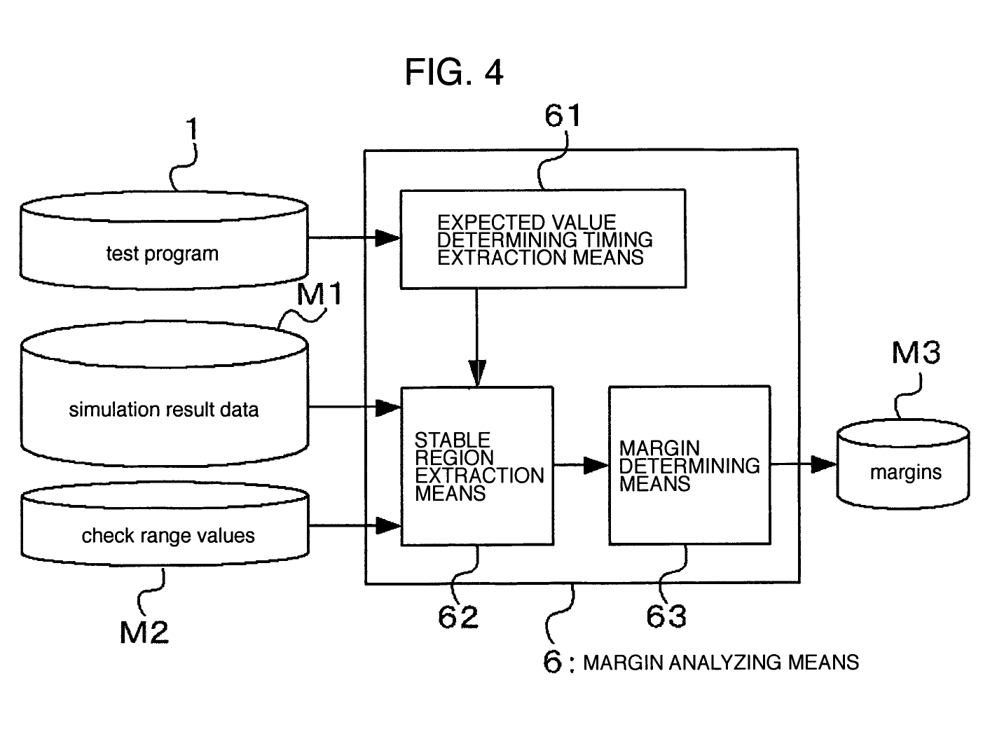

A second embodiment of a tester simulation system according to the invention is described hereinafter with reference to FIG. 4.

As shown in FIG. 4, a margin analyzing means 6 analyzes margins of respective expected value determining timings on the basis of data from a memory 1, a memory M1, and a memory M2 to thereby store the margins in a memory M3. The margin analyzing means 6 comprises an expected value determining timing extraction means 61, a stable region extraction means 62, and a margin determining means 63. The expected value determining timing extraction means 61 extracts expected value determining timing data from a test program of the memory 1. The stable region extraction means 62 extracts stable regions of output data of the memory M1 at respective check range values for every expected value determining timing according to the expected value determining timing data of the expected value determining timing extraction means 61. The margin determining means 63 determines the respective margins of the expected value determining timings from results of the stable region extraction means 62.

Operation of the above-described system is the same as that for the system shown in FIG. 1 except that the expected value determining timing extraction means 61 extracts the expected value determining timing data from the test program of the memory 1, omitting therefore description thereof.

### Third Embodiment

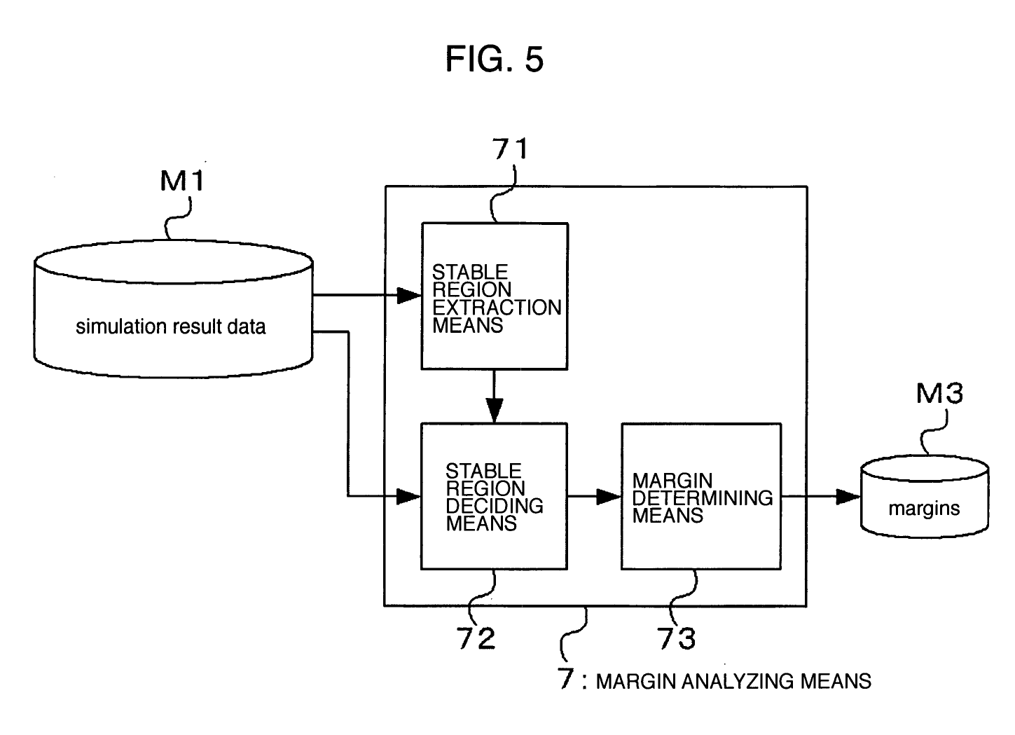

A third embodiment of a tester simulation system according to the invention is described hereinafter with reference to FIG. 5.

As shown in FIG. 5, a margin analyzing means 7 analyzes margins of respective expected value determining timings on the basis of data from a memory M1. The margin analyzing means 7 comprises a stable region extraction means 71, a stable region deciding means 72, and a margin determining means 73. The stable region extraction means 71 extracts stable regions of output data of the memory M1 for every test rate according to test rate data and output data of the memory M1. The stable region deciding means 72 decides stable regions from expected value determining timing data of the memory M1 according to results of the stable region extraction means 71. The margin determining means 73 determines the respective margins of the expected value determining timings from results of the stable region deciding means 72.

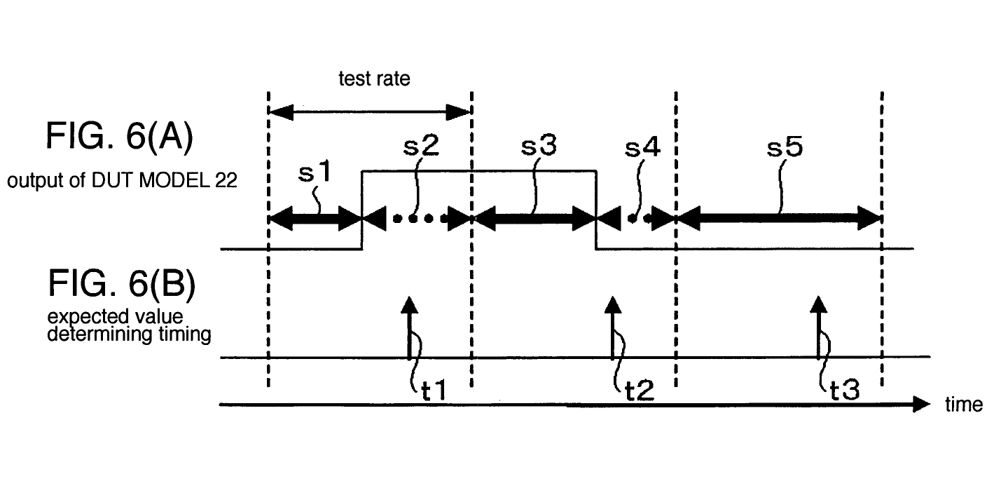

An operation of the above-described system is described with reference to FIG. 6. FIG. 6 is a schematic view illustrating the operation of the system shown in FIG. 5. FIG. 6(A) indicates an output of a DUT model 22, and FIG. 6(B) indicates the expected value determining timing.

The stable region extraction means 71 of the margin analyzing means 7 finds stable regions s1 to s5 at every variation point of the output data, and at every delimitation of the test rate as shown in FIG. 6 according to the test rate data and the output data from the memory M1. The stable region deciding means 72 extracts the stable regions s2, s4, s5, containing expected value determining timings t1 to t3, respectively, out of the stable regions s1 to s5, according to the expected value determining timing data of the memory M1.

The margin determining means 73 of the margin analyzing means 7 finds portions of the respective extract stable regions, in which a signal undergoes no change, overlapping each other, even if all the expected value determining timings t1 to t3 are shifted before or after relative to the respective test rates from the stable regions s2, s4, s5, respectively, to thereby find the respective margins of the expected value determining timings, storing the same in the memory M3.

### Fourth Embodiment

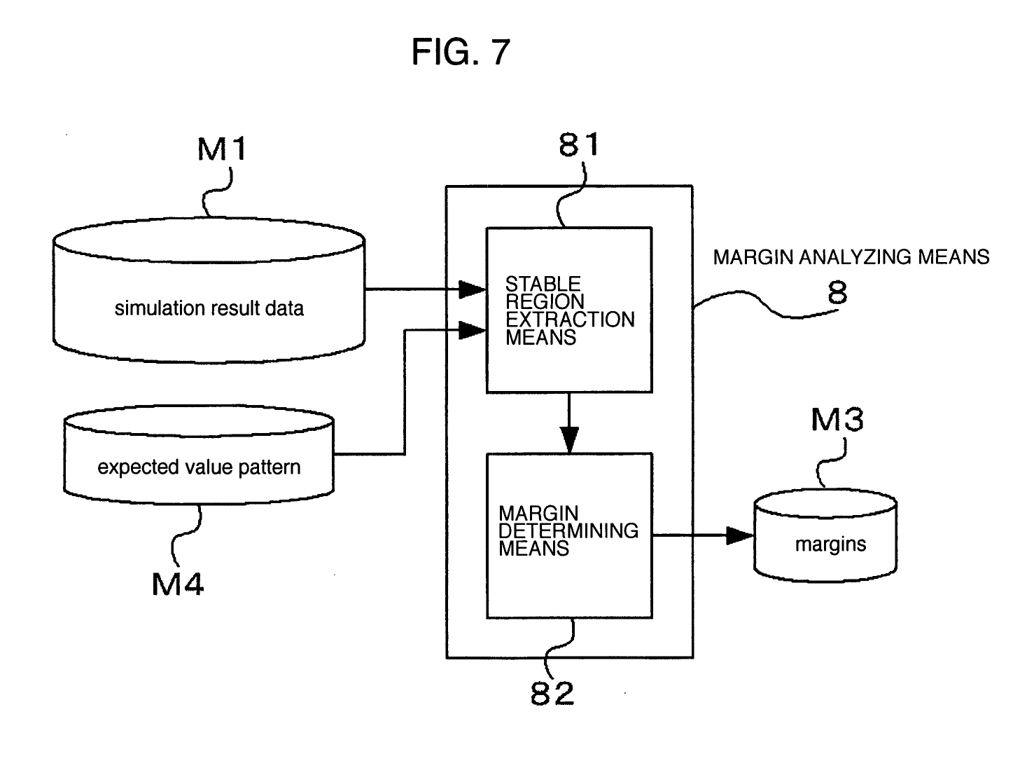

A fourth embodiment of a tester simulation system according to the invention is described hereinafter with reference to FIG. 7.

As shown in FIG. 7, a memory M4 stores an expected value pattern of a test program. A margin analyzing means 8 analyzes respective margins of expected value determining timings on the basis of output data of simulation result data as well as test rate data of a memory M1, and the expected value pattern of the memory M4 to thereby store the margins in a memory M3. The margin analyzing means 8 comprises a stable region extraction means 81, and a margin determining means 82. The stable region extraction means 81 extracts regions where the output data matches the respective expected value patterns for every test rate as respective stable regions. The margin determining means 82 determines the respective margins of the expected value determining timings, relative to the test rate, from results of the stable region extraction means 81

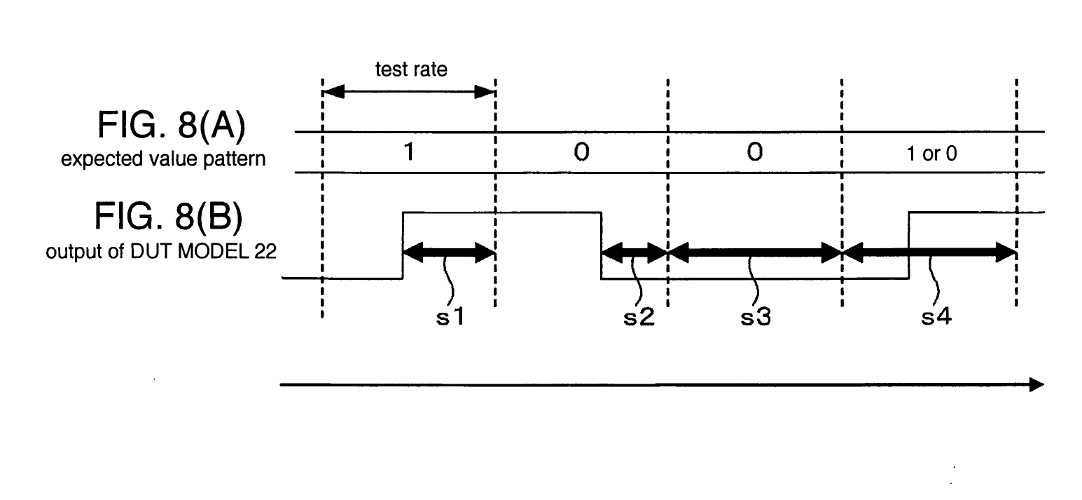

An operation of the above-described system is described with reference to FIG. 8. FIG. 8 is a schematic view illustrating the operation of the system shown in FIG. 7. FIG. 8(A) indicates the expected value pattern, and FIG. 8(B) indicates an output of a DUT model 22

The stable region extraction means 81 of the margin analyzing means 8 extracts a region of the test rate, in which the output data matches an expected value “1” according to the test rate data from the memory M1, as a stable region s1, as shown in FIG. 8. In the succeeding test rate, the stable region extraction means 81 similarly extracts a region where the output data matches an expected value “0”, as a stable region s2. By repeating such an operation, stable regions s3, s4 are extracted, respectively. Herein, since the expected value as matched is “1” or “0” in the stable region s4, the whole interval of this test rate becomes a stable region.

Then, the margin determining means 82 of the margin analyzing means 8 finds portions of the respective stable regions, in which a result of expected value comparison undergoes no change, overlapping each other, even if all the expected value determining timings are shifted before or after relative to the respective test rates from the stable regions s1 to s4, respectively, to thereby find the respective margins of the expected value determining timings, storing the same in the memory M3.

### Fifth Embodiment

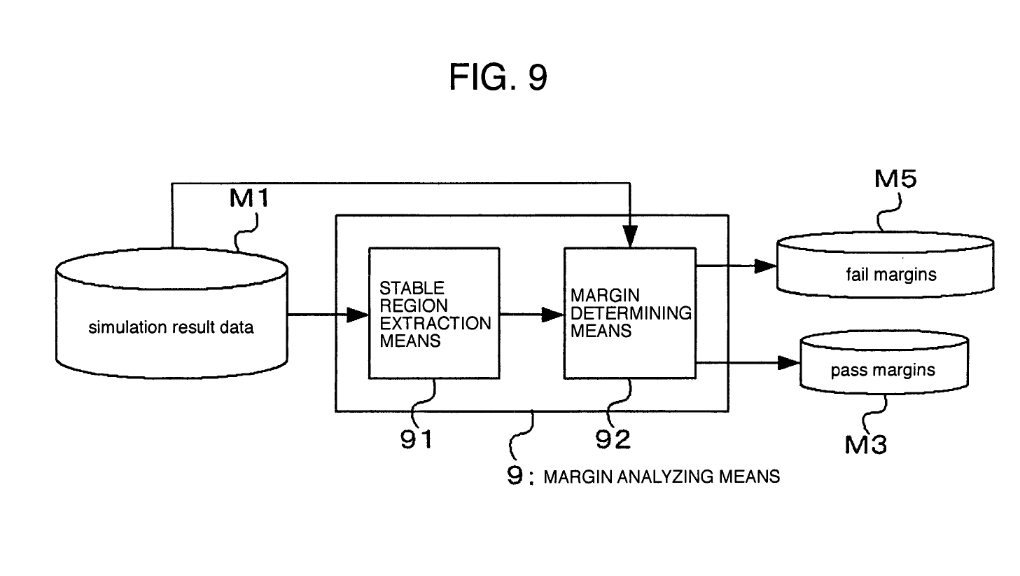

A fifth embodiment of a tester simulation system according to the invention is described hereinafter with reference to FIG. 9. As to the results of the simulations described hereinbefore, use has been made of passed simulation result data as a result of comparing all the outputs of the DUT model 22 with the expected value pattern, however, in this case, use is made of simulation result data including the case of a fail as well.

As shown in FIG. 9, a memory M5 stores respective margins of expected value determining timings in the case of a fail. A margin analyzing means 9 analyzes respective margins of expected value determining timings, that is, pass margins when pass/fail determination data indicate a pass, and fail margins when the pass/fail determination data indicate a fail, on the basis of output data of simulation result data, expected value determining timing data, test rate data, and the pass/fail determination data of a memory M1, to thereby store the pass margins and the fail margins in a memory M3 and the memory M5, respectively. The margin analyzing means 9 comprises a stable region extraction means 91, and a margin determining means 92. The stable region extraction means 91 extracts stable regions of the output of the memory M1, in respective test rate ranges, at every expected value determining timing, according to the test rate data, on the basis of the expected value determining timing data. The margin determining means 92 determines the respective margins of the expected value determining timings, by a pass or a fail, from results of the stable region extraction means 91, and the pass/fail determination data of the memory M1, for the respective test rates.

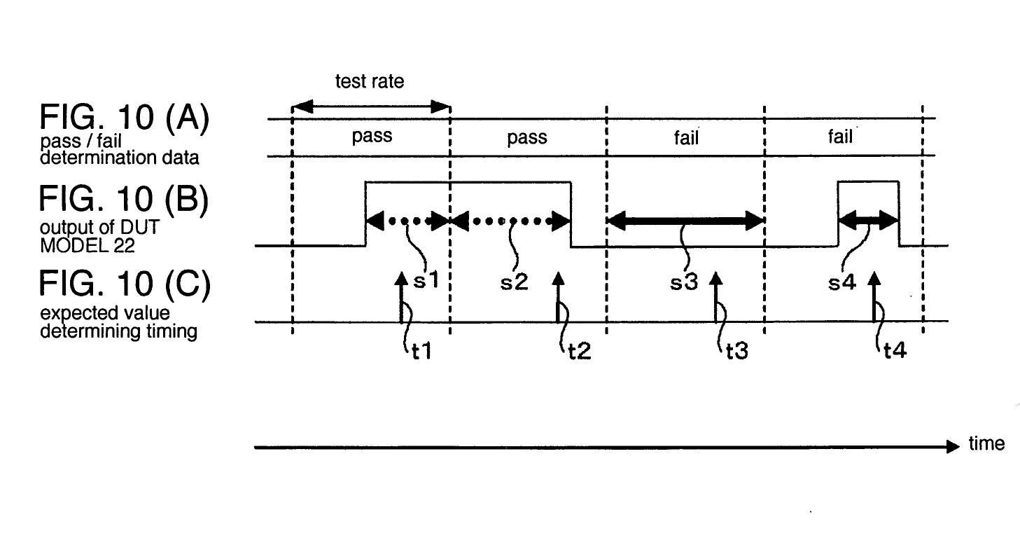

An operation of the above-described system is described with reference to FIG. 10. FIG. 10 is a schematic view illustrating the operation of the system shown in FIG. 9. FIG. 10(A) indicates the pass/fail determination data, 10(B) indicates an output of a DUT model 22, and 10(C) indicates the expected value determining timing.

The stable region extraction means 91 of the margin analyzing means 9 extracts a stable region s1 where a signal of the output data of the memory M1 is not changing at the same signal level as that for the expected value determining timing in a test rate as shown in FIG. 10, according to the test rate data from the memory M1. More specifically, the stable region extraction means 91 determines the stable region by comparing a time of the expected value determining timing with a signal change-time of the output data in the test rate. By repeating such an operation, stable regions s2 to s4 at expected value determining timings t2 to t4, respectively, are extracted.

The margin determining means 92 of the margin analyzing means 9 classifies the stable regions s1 to s4 into the stable regions s1, s2, at the time of a pass, and the stable regions s3, s4, at the time of a fail, according to the pass/fail determination data of the memory M1. The margin determining means 92 finds portions of the respective extract stable regions, in which a signal undergoes no change, overlapping each other, even if the expected value determining timings t1, t2 of the stable regions s1, s2, at the time of the pass, respectively are shifted before or after relative to the respective test rates to thereby find the respective margins of the expected value determining timings, storing the same in the memory M3. The margin determining means 92 further finds ranges of the respective extract stable regions, in which a signal undergoes no change, overlapping each other, even if the expected value determining timings t3, t4 of the stable regions s3, s4, at the time of the fail, respectively, are shifted relative to the respective test rates to thereby store the ranges in the memory M5.

Thus, the margin analyzing means 9 finds the respective margins of the expected value determining timings, at times of a fail, according to the output data and the pass/fail determination data so that it is possible to find whether or not the expected value comparison result can be passed in all the test rates by changing the respective expected value determining timings if the respective margins at the time of fail are small.

### Sixth Embodiment

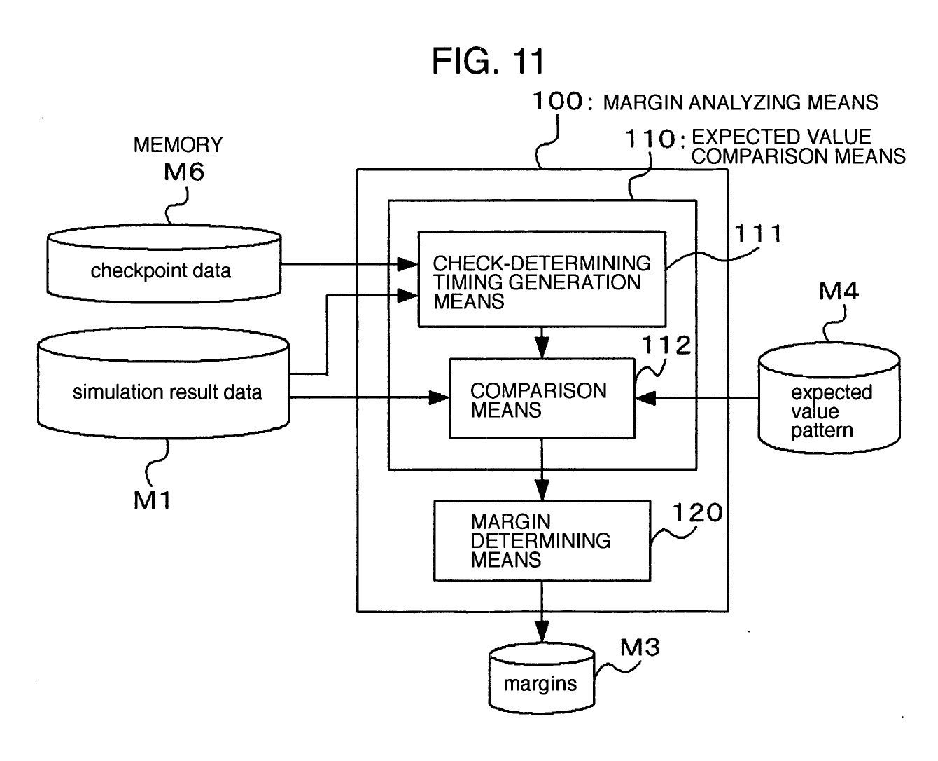

A sixth embodiment of a tester simulation system according to the invention is described hereinafter with reference to FIG. 11.

As shown in FIG. 11, a memory 6 stores a plurality of checkpoint data indicating checkpoints as expected value determining timings. Herein, checkpoint data are defined by a relative time from the respective expected value determining timings. A margin analyzing means 100 analyzes respective margins of the expected value determining timings on the basis of output data of simulation result data, and expected value determining timing data of a memory M1, an expected value pattern of a memory M4, and the checkpoint data of the memory M6 to thereby store the margins in a memory M3. The margin analyzing means 100 comprises an expected value comparison means 110, and a margin determining means 120. The expected value comparison means 110 generates check-determining timings according to the expected value determining timings, and the checkpoint data to thereby compare the output data with the expected value pattern at such timings. And the expected value comparison means 110 comprises a check-determining timing generation means 111, and a comparison means 112. The check determining timing generation means 111 adds the checkpoint data to the expected value determining timings to thereby generate the check-determining timings. The comparison means 112 compares the output data with the expected value pattern at the respective check-determining timings. The margin determining means 120 determines the respective margins of the expected value determining timings from results of the expected value comparison means 110.

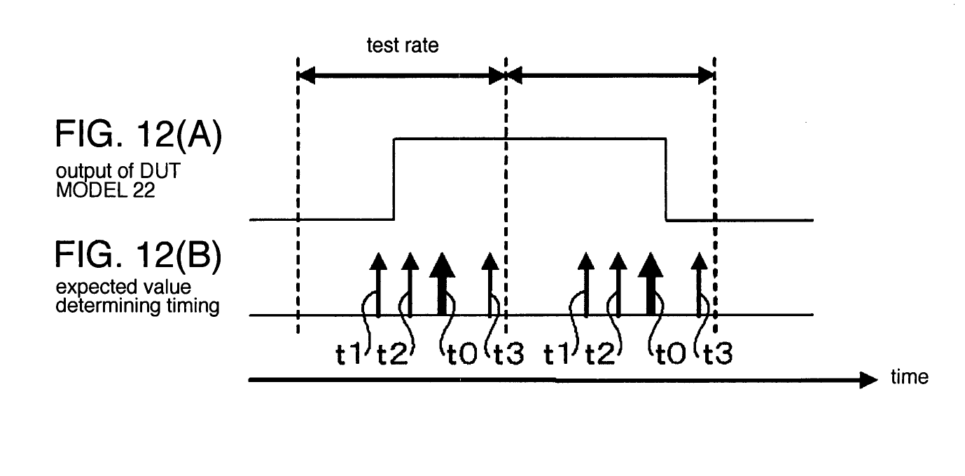

An operation of the above-described system is described with reference to FIG. 12. FIG. 12 is a schematic view illustrating the operation of the system shown in FIG. 11. FIG. 12(A) indicates an output of a DUT model 22, and FIG. 12(B) indicates the expected value determining timing.

The check determining timing generation means 111 of the expected value comparison means 110 adds the checkpoint data to an expected value determining timing t0 to thereby generate a check determining timing t1 as shown in FIG. 12 (B). Then, the comparison means 112 compares the output data of the memory M1 with an expected value of the memory M4 at the check-determining timing t1 of the check determining timing generation means 111 to thereby output a pass or a fail, together with check determining timing data. The check determining timing generation means 111 similarly adds the checkpoint data to the expected value determining timing t0 to thereby generate a check determining timing t2 as shown in FIG. 12 (B). Subsequently, the comparison means 112 compares the output data with an expected value at the check-determining timing t2 to thereby output a pass or a fail, together with check determining timing data. Such an operation is repeated and determination on a pass or a fail is also executed at a check-determining timing t3.

The margin determining means 120 of the margin analyzing means 100 determines if the simulation result data are all passed at the respective check-determining timings t1 to t3, and if so, finds the respective margins of the expected value determining timings, relative to respective test rates, in respective check-determining timing intervals (intervals each including the expected value determining timing) to be thereby stored in the memory M3.

The check determining timing generation means 111 is shown to have a configuration of finding the check-determining timings according to the expected value determining timing data, and the checkpoint data, however, the check determining timing generation means may have a configuration of finding the check-determining timings according to test rate data of simulation result data and the checkpoint data. In this case, the checkpoint data are defined by a relative time from a starting point of each of the test rates. Further, the checkpoint data may define a time difference between the starting point of each of the test rates and succeeding check determining timing.

Further, with the present embodiment, a configuration is shown wherein the expected value determining timings are obtained from the simulation result data, however, a configuration may be adopted wherein the expected value determining timings are obtained from a test program.

### Seventh Embodiment

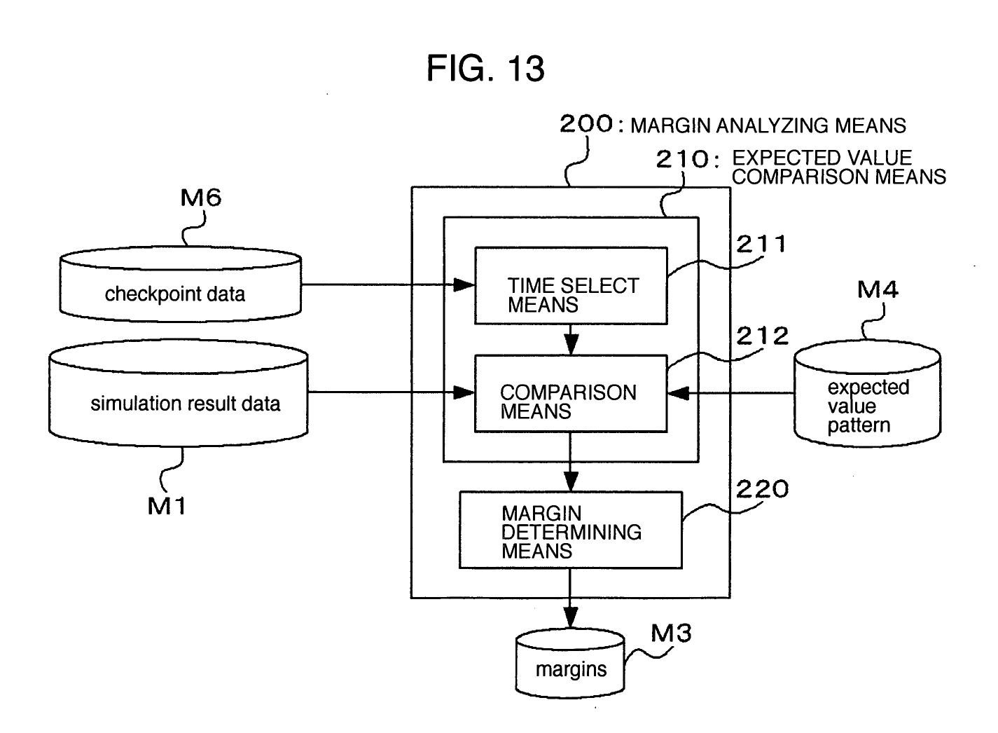

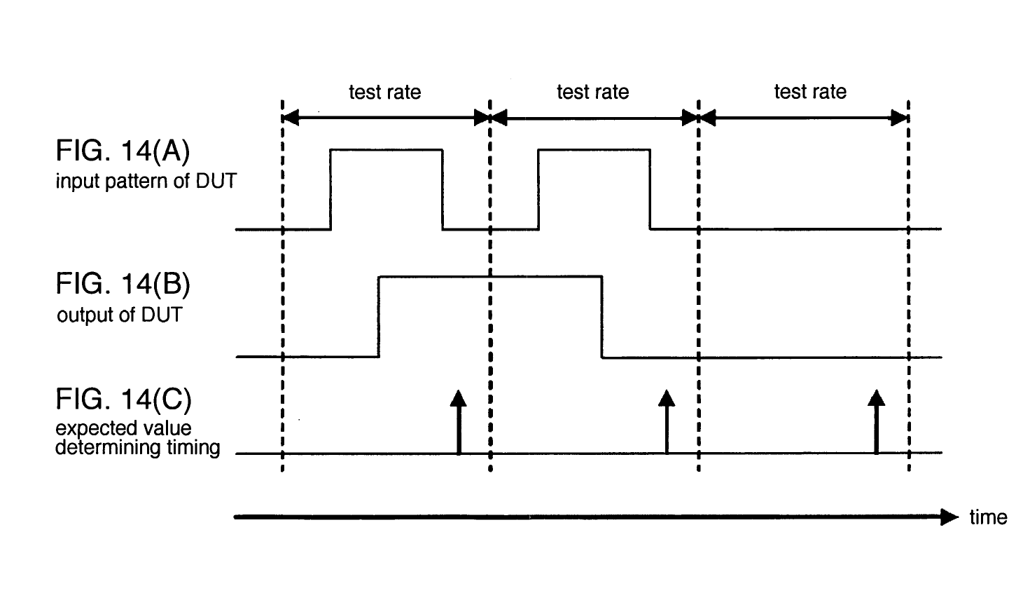

A seventh embodiment of a tester simulation system according to the invention is described hereinafter with reference to FIG. 13.

As shown in FIG. 13, a memory M6 stores a plurality of checkpoint data defined by absolute time. A margin analyzing means 200 analyzes respective margins of expected value determining timings on the basis of output data of simulation result data of a memory M1, an expected value pattern of a memory M4, and the checkpoint data of the memory M6 to thereby store the margins in a memory M3. The margin analyzing means 200 comprises an expected value comparison means 210, and a margin determining means 220. The expected value comparison means 210 compares the output data with the expected value pattern at timings of the checkpoint data. And the expected value comparison means 210 comprises a time select means 211, and a comparison means 212. The time select means 211 selects check-determining timings out of the checkpoint data. The comparison means 212 compares the output data with the expected value patterns at the respective check-determining timings. The margin determining means 220 determines the respective margins of the value determining timings from results of the expected value comparison means 210.

An operation of the above-described system is described hereinafter.

The time select means 211 of the expected value comparison means 210 selects the check-determining timings out of the checkpoint data of the memory M6. More specifically, as the checkpoint data are compiled by the test rate, or by the sequence of presence of the respective test rates, the time select means 211 causes the respective check-determining timings to be outputted in sequence. Subsequently, the comparison means 212 compares the output data of the memory M1 with an expected value of the memory M4 at the check-determining timing of the time select means 211 to thereby output a pass or a fail, together with check determining timing data.

The margin determining means 220 of the margin analyzing means 200 determines if the simulation result data are all passed at every check-determining timing, and if so, finds the respective margins of the expected value determining timings, relative to the respective test rates, in respective check-determining timing intervals (intervals each including the expected value determining timing) to be thereby stored in the memory M3.

What is claimed is:

1. A tester simulation system for executing a test of a device under test by use of a tester by running a simulation using a DUT model for simulating an operation of the device under test, and a tester model for simulating an operation of the tester, said tester simulation system comprising:
a margin analyzing means for analyzing margins of respective expected value determining timings on the basis of output data of the DUT model.

2. A tester simulation system according to claim 1, wherein the margin analyzing means finds the margins at least in the cases of a fail on the basis of pass/fail determination data representing results of comparison of the output data of the DUT model with an expected value pattern.

3. A tester simulation system according to claim 1 or 2, wherein the margin analyzing means comprises:
a stable region extraction means for extracting stable regions of the output data of the DUT model in respective check ranges; and
a margin determining means for determining the respective margins of the expected value determining timings from results of the stable region extraction means.

4. A tester simulation system according to claim 1 or 2, wherein the margin analyzing means comprises:
an expected value comparison means for comparing the output data of the DUT model with the respective expected value patterns according to the expected value determining timings, and checkpoints; and
a margin determining means for determining the respective margins of the expected value determining timings from results of the expected value comparison means.

5. A tester simulation system according to any one of claims 1 or 2, further comprising an acquisition means for acquiring at least the output data of the DUT model for use in the margin analyzing means.

6. A tester simulation method for executing a test of a device under test by use of a tester by running a simulation using a DUT model for simulating an operation of the device under test, and a tester model for simulating an operation of the tester, said method comprising the step of:
analyzing margins of respective expected value determining timings on the basis of output data of the DUT model.

7. A tester simulation method according to claim 6, further comprising the step of finding margins at least in the cases of a fail on the basis of pass/fail determination data representing results of comparison of the output data of the DUT model with respective expected value patterns.

8. A tester simulation method according to claim 6 or 7, further comprising the steps of:
extracting stable regions of the output data of the DUT model in respective check ranges; and
determining the respective margins of the expected value determining timings from the respective stable regions.

9. A tester simulation method according to claim 6 or 7, further comprising the steps of:
comparing the output data of the DUT model with the respective expected value patterns according to the expected value determining timings; and
checkpoints, and determining the respective margins of the expected value determining timings from results of comparison.
